(19) United States
(12) Patent Application Publication
(10) Pub. No.: US 2025/0247948 A1
(43) Pub. Date: Jul. 31, 2025

(54) INPUT/OUTPUT APPARATUS

(71) Applicant: REALTEK SEMICONDUCTOR CORP., Hsinchu (TW)

(72) Inventors: Heng-Chia Hsu, Hsinchu (TW); Guan-Yi Li, Hsinchu (TW)

(73) Assignee: REALTEK SEMICONDUCTOR CORP., Hsinchu (TW)

(21) Appl. No.: 18/949,004

(22) Filed: Nov. 15, 2024

(30) Foreign Application Priority Data
Jan. 30, 2024 (TW) 113103630

(51) Int. Cl. H05K 1/02

(52) U.S. Cl. CPC H05K 1/0219; H05K 2201/093

(57) ABSTRACT

An input/output apparatus includes a plurality of transmission pad groups and a plurality of grounding pad groups. Each transmission pad group includes a first transmission pad and a second transmission pad. Each grounding pad group includes a first grounding pad and a second grounding pad, the first grounding pad and the second grounding pad are respectively located on two opposite outer sides of the first transmission pad and the second transmission pad and are at a spacing. A side of the first grounding pad is provided with a first recessed portion, and a side of the second grounding pad is provided with a second recessed portion. A first shortest distance between the first transmission pad and the first recessed portion and a second shortest distance between the second transmission pad and the second recessed portion are separately greater than the spacing.

### CROSS-REFERENCE TO RELATED APPLICATION

This non-provisional application claims priority under 35 U.S.C. § 119(a) to patent application Ser. No. 11/310,3630 filed in Taiwan, R.O.C. on Jan. 30, 2024, the entire contents of which are hereby incorporated by reference.

### BACKGROUND

### Technical Field

The present invention relates to an input/output apparatus, and in particular, to an input/output apparatus used in a high-speed transmission circuit.

### Related Art

A high-speed transmission circuit uses an input/output pad (I/O Pad) as an interface for external transmission. In adjacent high-speed transmission circuits, as a transmission speed increases, parasitic capacitance between an input/output pad and an adjacent input/output pad will cause mutual interference, resulting in poor signal quality, and a transmission signal specification cannot be met.

To avoid the problem of poor signal quality caused by mutual interference, a grounding pad or a ground shield may be added between the input/output pad and the adjacent input/output pad. The grounding pad is used as an example, additional parasitic capacitance will be generated between the input/output pad and the grounding pad, and excessive large parasitic capacitance has negative impact on performance of the circuit. To reduce the parasitic capacitance between the input/output pad and the grounding pad, it is necessary to increase a spacing between the input/output pad and the grounding pad, such as increasing the spacing to twice (2*S) the original spacing (S). However, this will cause an outline of the entire circuit to become longer and affect a side length of the chip. An increase in the side length of the chip is equivalent to an increase of an area and will also increase manufacturing costs.

Therefore, in the high-speed transmission circuit, the spacing is increased to reduce the parasitic capacitance. However, when an advanced process is used, an area of a digital circuit becomes smaller, and eventually a relative length of the input/output pad limits a size of the entire integrated circuit (IC).

### SUMMARY

The present invention provides an input/output apparatus suitable for a plurality of high-speed transmission circuits, where the input/output apparatus includes a plurality of transmission pad groups and a plurality of grounding pad groups. The plurality of transmission pad groups are of the same number as the high-speed transmission circuits and respectively correspond to the high-speed transmission circuits. Each transmission pad group includes a first transmission pad and a second transmission pad, and the first transmission pad and the second transmission pad are connected to the same side of a corresponding high-speed transmission circuit. The plurality of grounding pad groups are of the same number as the transmission pad groups and respectively correspond to the transmission pad groups. Each grounding pad group includes a first grounding pad and a second grounding pad, and the first grounding pad and the second grounding pad are respectively located on two opposite outer sides of the first transmission pad and the second transmission pad and are at a spacing. A side that is of the first grounding pad and that is close to the first transmission pad is provided with a first recessed portion, and a side that is of the second grounding pad and that is close to the second transmission pad is provided with a second recessed portion, so that a first shortest distance between the first transmission pad and an inner edge of the first recessed portion and a second shortest distance between the second transmission pad and an inner edge of the second recessed portion are separately greater than the spacing.

In some embodiments, the first shortest distance and the second shortest distance are at least twice the spacing.

In some embodiments, the first grounding pad further includes two first grounding units, and sides that are of the two first grounding units and that correspond to the first transmission pad form the first recessed portion together; and the second grounding pad further includes two second grounding units, and sides that are of the two second grounding units and that correspond to the second transmission pad form the second recessed portion together.

In some embodiments, there is a gap between the two first grounding units; and there is a gap between the two second grounding units.

In some embodiments, the first transmission pad and the second transmission pad are polygonal pads, and the first recessed portion and the second recessed portion are matching recessed portions corresponding to the polygonal pads.

In some embodiments, the first transmission pad and the second transmission pad are hexagonal pads, and the first recessed portion and the second recessed portion are triangular recessed portions corresponding to the hexagonal pads.

In some embodiments, the first grounding pad is connected to an external grounding apparatus through at least one first grounding wire; and the second grounding pad is connected to the external grounding apparatus through at least one second grounding wire.

In some embodiments, a height of the first grounding pad meets a minimum height for setting the at least one first grounding wire; and a height of the second grounding pad meets a minimum height for setting the at least one second grounding wire.

In some embodiments, at least one of the two first grounding units is connected to an external grounding apparatus through at least one first grounding wire; and at least one of the two second grounding units is connected to the external grounding apparatus through at least one second grounding wire.

In some embodiments, heights of the two first grounding units separately meet the minimum height for setting the first grounding wire; and heights of the two second grounding units separately meet the minimum height for setting the second grounding wire.

In some embodiments, the high-speed transmission circuits are a peripheral component interactive connection apparatus (PCIe), a universal serial bus apparatus (USB 3.0/3.1/3.2), a high-definition multimedia interface (HDMI) apparatus, a display port (DP) interface apparatus, and a serial advanced technology attachment (SATA) apparatus.

In conclusion, to shorten an outline of the high-speed transmission circuit and reduce parasitic capacitance between the transmission pad and the grounding pad, the present invention proposes an input/output apparatus that increases a horizontal distance between the transmission pad and the grounding pad through a design of the recessed portion on the grounding pad, to reduce the parasitic capacitance between the transmission pad and the grounding pad without additionally increasing the outline, thereby achieving good signal quality and meeting a transmission signal specification.

### BRIEF DESCRIPTION OF THE DRAWINGS

FIG. 1 is a schematic architectural diagram of a high-speed transmission circuit and an input/output apparatus of the high-speed transmission circuit according to a first embodiment of the present invention;

FIG. 2 is a schematic architectural diagram of a high-speed transmission circuit and an input/output apparatus of the high-speed transmission circuit according to a second embodiment of the present invention;

FIG. 3 is a schematic architectural diagram of a high-speed transmission circuit and an input/output apparatus of the high-speed transmission circuit according to a third embodiment of the present invention;

FIG. 4 is a schematic architectural diagram of a high-speed transmission circuit and an input/output apparatus of the high-speed transmission circuit according to a fourth embodiment of the present invention;

FIG. 5 is a schematic architectural diagram of a high-speed transmission circuit and an input/output apparatus of the high-speed transmission circuit according to a fifth embodiment of the present invention; and

FIG. 6 is a schematic architectural diagram of a high-speed transmission circuit and an input/output apparatus of the high-speed transmission circuit according to a sixth embodiment of the present invention.

### DETAILED DESCRIPTION

The following provides detailed descriptions of preferred embodiments. However, the embodiments are only used as examples and do not limit the protection scope of the present invention. In addition, some components are omitted in the drawings in the embodiments to clearly illustrate technical features of the present invention. Same reference numbers in all drawings are used to represent same or similar components.

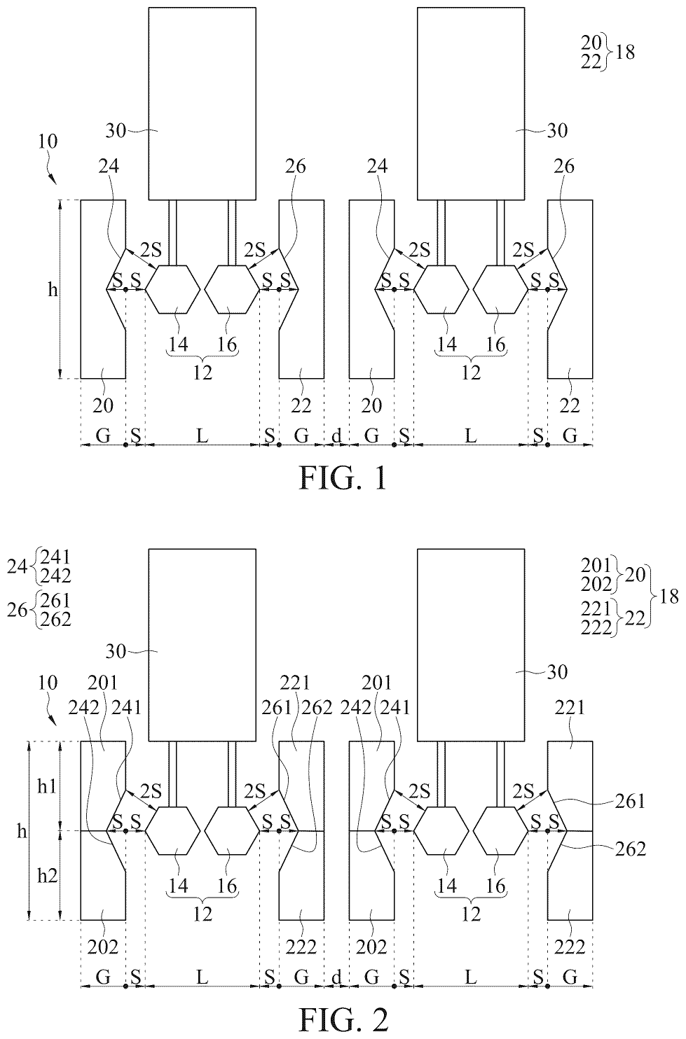

FIG. 1 is a schematic architectural diagram of a high-speed transmission circuit and an input/output apparatus of the high-speed transmission circuit according to a first embodiment of the present invention. Referring to FIG. 1, an input/output apparatus 10 is suitable for a plurality of high-speed transmission circuits 30, and includes a plurality of transmission pad groups 12 and a plurality of grounding pad groups 18. The transmission pad groups 12 are of the same number as the high-speed transmission circuits 30 and respectively correspond to the high-speed transmission circuits 30. The grounding pad groups 18 are of the same number as the transmission pad groups 12 and respectively correspond to the transmission pad groups 12, so that each high-speed transmission circuit 30 corresponds to a transmission pad group 12 and a grounding pad group 18. In this embodiment, two high-speed transmission circuits 30 are used as an example in the present invention. The input/output apparatus 10 also correspondingly includes two transmission pad groups 12 and two grounding pad groups 18. However, the number is not limited in the present invention.

In the input/output apparatus 10, each high-speed transmission circuit 30 is connected to a transmission pad group 12. Each transmission pad group 12 includes a first transmission pad 14 and a second transmission pad 16. The transmission pad 14 and the second transmission pad 16 are connected to the same side of the corresponding high-speed transmission circuit 30, so that the high-speed transmission circuit 30 receives or sends a signal through the first transmission pad 14 and the second transmission pad 16. Each high-speed transmission circuit 30 is provided with a grounding pad group 18. Each grounding pad group 18 includes a first grounding pad 20 and a second grounding pad 22. The first grounding pad 20 and the second grounding pad 22 are respectively located on two opposite outer sides of the first transmission pad 14 and the second transmission pad 16, so that a distance between vertical tangent lines of the first grounding pad 20 and the first transmission pad 14 is a spacing S, and a distance between vertical tangent lines of the second grounding pad 22 and the second transmission pad 16 is also the spacing S. A side that is of the first grounding pad 20 and that is close to the first transmission pad 14 is provided with a first recessed portion 24, and a side that is of the second grounding pad 22 and that is close to the second transmission pad 16 is provided with a second recessed portion 26, so that a first shortest distance between the first transmission pad 14 and an inner edge of the first recessed portion 24 and a second shortest distance between the second transmission pad 16 and an inner edge of the second recessed portion 26 are separately greater than the spacing S. The first transmission pad 14 and the second transmission pad 16 are polygonal pads, and the first recessed portion 24 and the second recessed portion 26 are matching recessed portions corresponding to the polygonal pads, so that a distance between an outer edge of the first transmission 14 and the inner edge of the first recessed portion 24 is maintained at the first shortest distance, and a distance between an outer edge of the second transmission pad 16 and the inner edge of the second recessed portion 26 is maintained at the second shortest distance. In an embodiment, the first shortest distance and the second shortest distance are at least greater than the spacing S, for example, twice (2S) the spacing S. In embodiments of the present invention, twice (2S) the spacing S is used as an example. However, the present invention is not limited thereto.

In an embodiment, as shown in FIG. 1, the first transmission pad 14 and the second transmission pad 16 are hexagonal pads, and the first recessed portion 24 and the second recessed portion 26 are triangular recessed portions corresponding to the hexagonal pads, so that the first shortest distance between the first transmission pad 14 and an inner edge of the triangle of the first recessed portion 24 and the second shortest distance between the second transmission pad 16 and an inner edge of the triangle of the second recessed portion 26 are separately at least twice (2S) the spacing S. Specifically, when a length (a distance required for differential input/output pads) from an outer side of the first transmission pad 14 to an outer side of the second transmission pad 16 is L, widths of the first grounding pad 20 and the second grounding pad 22 are G, and a distance between the second grounding pad 22 and the first grounding pad 20 of another adjacent high-speed transmission circuit is d. In this embodiment, on a premise that a length of an outline edge of the entire high-speed transmission circuit 30 (two high-speed transmission circuits 30 are included in this embodiment) is maintained at 4*G+4*S+2*L+d, through an action of the first recessed portion 24 and the second recessed portion 26, additional distances of the spacing S are cut on the first grounding pad 20 and the second grounding pad 22, so that the first shortest distance and the second shortest distance become twice (2S) the spacing S, to reduce parasitic capacitance between the first transmission pad 14 and the first grounding pad 20 and between the second transmission pad 16 and the second grounding pad 22.

FIG. 2 is a schematic architectural diagram of a high-speed transmission circuit and an input/output apparatus of the high-speed transmission circuit according to a second embodiment of the present invention. Referring to FIG. 2, in an input/output apparatus 10, each high-speed transmission circuit 30 is connected to a transmission pad group 12. Each transmission pad group 12 includes a first transmission pad 14 and a second transmission pad 16, and the first transmission pad 14 and the second transmission pad 16 are connected to the same side of a corresponding high-speed transmission circuit 30. In this embodiment, the first transmission pad 14 and the second transmission pad 16 are also hexagonal pads. Each high-speed transmission circuit 30 is provided with a grounding pad group 18. Each grounding pad group 18 includes a first grounding pad 20 and a second grounding pad 22, and the first grounding pad 20 and the second grounding pad 22 are respectively located on two opposite outer sides of the first transmission pad 14 and the second transmission pad 16. The first grounding pad 20 further includes two connected first grounding units 201 and 202. Sides that are of the two first grounding units 201 and 202 and that correspond to the first transmission pad 14 form the first recessed portion 24 together. In other words, a notch 241 is cut at a connecting end of the first grounding unit 201 near the side of the first transmission pad 14, and another notch 242 is cut at a connecting end of the other first grounding unit 202 near the side of the first transmission pad 14, so that the two notches 241 and 242 form the first recessed portion 24 together, and the first recessed portion 24 correspondingly matches the first transmission pad 14, and the first shortest distance between the outer edge of the first transmission pad 14 and the inner edge of the first recessed portion 24 is twice (2S) the spacing S. The second grounding pad 22 further includes two connected second grounding units 221 and 222. Sides that are of the two second grounding units 221 and 222 and that correspond to the second transmission pad 16 form the second recessed portion 26 together. In other words, a notch 261 is cut at a connecting end of the second grounding unit 221 near the side of the second transmission pad, and another notch 262 is cut at a connecting end of the other second grounding unit 222 near the side of the second transmission pad 16, so that the two notches 261 and 262 form the second recessed portion 26 together, and the second recessed portion 26 correspondingly matches the second transmission pad 16, and the second shortest distance between the outer edge of the second transmission pad 16 and the inner edge of the second recessed portion 26 is twice (2S) the spacing S. Based on this, on a premise that a length of an outline edge of the entire high-speed transmission circuit 30 is maintained at 4*G+4*S+2*L+d, through an action of the first recessed portion 24 and the second recessed portion 26, in this embodiment, additional distances of the spacing S are cut on the first grounding pad 20 and the second grounding pad 22, so that the first shortest distance and the second shortest distance become twice (2S) the spacing S, effectively reducing parasitic capacitance between the transmission pad 14 and the first grounding pad 20 and between the second transmission pad 16 and the second grounding pad 22.

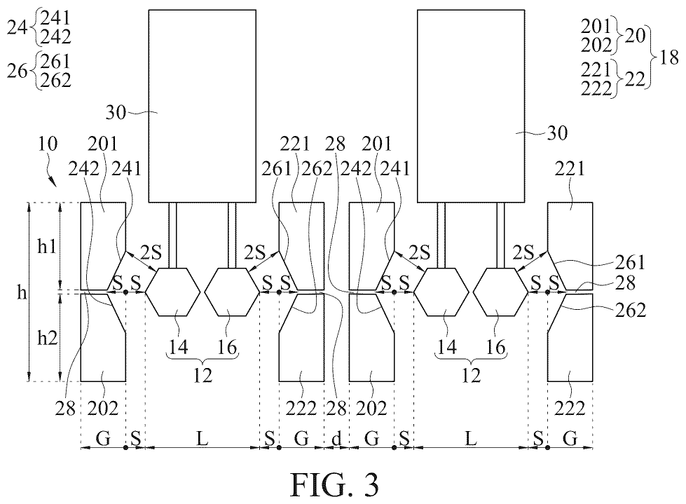

FIG. 3 is a schematic architectural diagram of a high-speed transmission circuit and an input/output apparatus of the high-speed transmission circuit according to a third embodiment of the present invention. Referring to FIG. 3, in an input/output apparatus 10, each high-speed transmission circuit 30 is connected to a transmission pad group 12. Each transmission pad group 12 includes a first transmission pad 14 and a second transmission pad 16, and the first transmission pad 14 and the second transmission pad 16 are connected to the same side of a corresponding high-speed transmission circuit 30. In this embodiment, the first transmission pad 14 and the second transmission pad 16 are hexagonal pads. Each high-speed transmission circuit 30 is provided with a grounding pad group 18. Each grounding pad group 18 includes a first grounding pad 20 and a second grounding pad 22, and the first grounding pad 20 and the second grounding pad 22 are respectively located on two opposite outer sides of the first transmission pad 14 and the second transmission pad 16. The first grounding pad 20 further includes two longitudinally arranged first grounding units 201 and 202, and there is a gap 28 between the two first grounding units 201 and 202. A notch 241 is cut on a side that is of the first grounding unit 201 on a side of the gap 28 and that is near the first transmission pad 14, and another notch 242 is also cut on a side that is of the first grounding unit 202 on the other side of the gap 28 and that is near the first transmission pad 14, so that the two notches 241 and 242 form a first recessed portion 24 together, and the first recessed portion 24 correspondingly matches the first transmission pad 14, and a first shortest distance between an outer edge of the first transmission pad 14 and an inner edge of the first recessed portion 24 is twice (2S) the spacing S. The second grounding pad 22 further includes two longitudinally arranged second grounding units 221 and 222, and there is a gap 28 between the two second grounding units 221 and 222. A notch 261 is cut on a side that is of the second grounding unit 221 on a side of the gap 28 and that is near the second transmission pad 16, and another notch 262 is also cut on a side that is of the second grounding unit 222 on the other side of the gap 28 and that is near the second transmission pad 16, so that the two notches 261 and 262 form the second recessed portion 26 together, and the second recessed portion 26 correspondingly matches the second transmission pad 16, and a second shortest distance between an outer edge of the second transmission pad 16 and an inner edge of the second recessed portion 26 is also twice (2S) the spacing S. Based on this, on a premise that a length of an outline edge of the entire high-speed transmission circuit 30 is maintained at 4*G+4*S+2*L+d, through an action of the first recessed portion 24 and the second recessed portion 26, in this embodiment, additional distances of the spacing S are cut on the first grounding pad 20 and the second grounding pad 22, so that the first shortest distance and the second shortest distance become twice (2S) the spacing S, effectively reducing parasitic capacitance between the transmission pad 14 and the first grounding pad 20 and between the second transmission pad 16 and the second grounding pad 22.

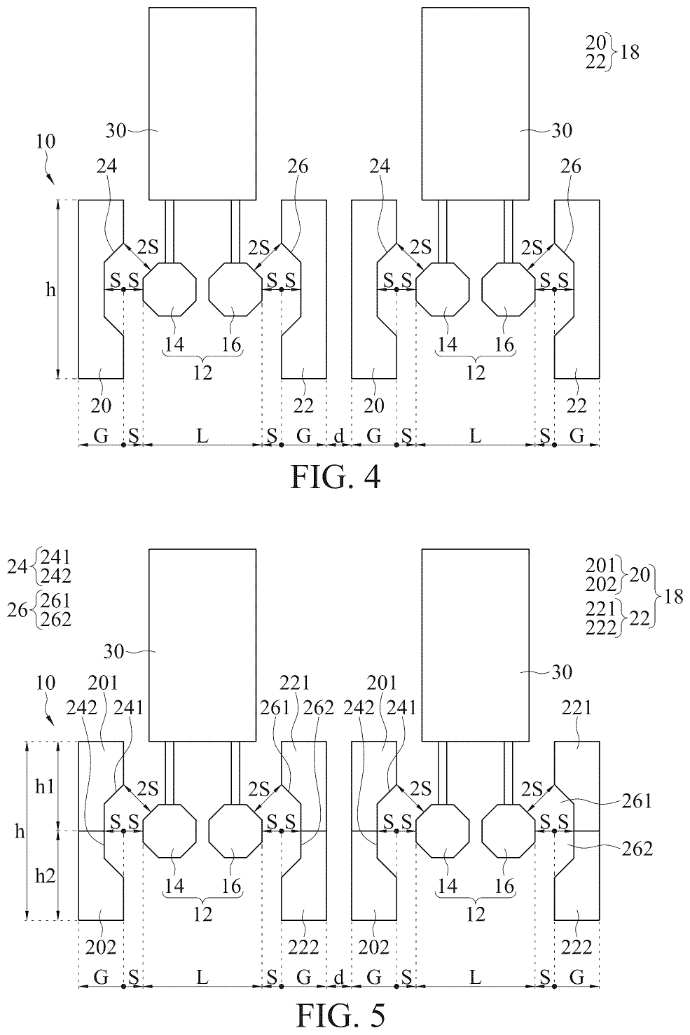

Because the first transmission pad 14 and the second transmission pad 16 are polygonal pads, and the first recessed portion 24 and the second recessed portion 26 are matching recessed portions corresponding to the polygonal pads, in addition to the hexagonal pads mentioned above, the first transmission pad 14 and the second transmission pad 16 also have other implementation forms, but this is not limited in the present invention. FIG. 4 is a schematic architectural diagram of a high-speed transmission circuit and an input/output apparatus of the high-speed transmission circuit according to a fourth embodiment of the present invention. Referring to FIG. 4, in an input/output apparatus 10, a first transmission pad 14 and a second transmission pad 16 are octagonal pads, and a first recessed portion 24 and a second recessed portion 26 are trapezoidal recessed portions corresponding to the octagonal pads, so that a first shortest distance between an outer side of the first transmission pad 14 and a trapezoidal inner edge of the first recessed portion 24 and a second shortest distance between an outer side of the second transmission pad 16 and a trapezoidal inner edge of the second recessed portion 26 are separately greater than the spacing S, and twice (2S) the spacing is used as an example, but this is not limited in the present invention. In addition to the first transmission pad 14 and the second transmission pad 16, as well as the first recessed portion 24 and the second recessed portion 26, the remaining structures and functions are the same as the embodiment described in FIG. 1, and details are not described herein again.

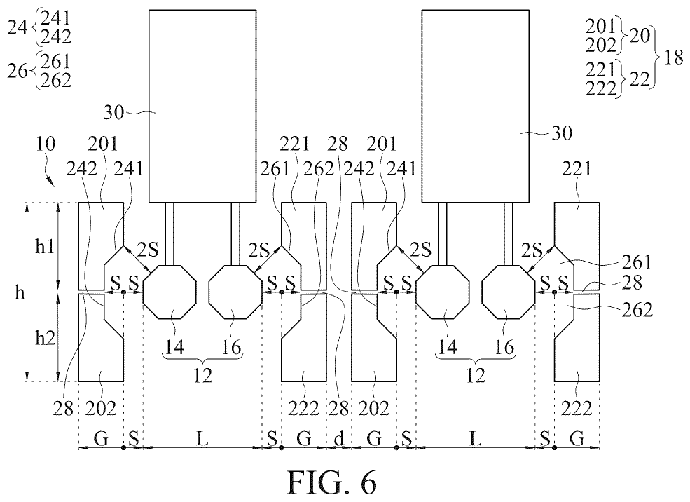

Similarly, FIG. 5 is a schematic architectural diagram of a high-speed transmission circuit and an input/output apparatus of the high-speed transmission circuit according to a fifth embodiment of the present invention. Referring to FIG. 5, in addition to octagonal pads of the first transmission pad 14 and the second transmission pad 16, as well as trapezoidal recessed portions of the first recessed portion 24 and the second recessed portion 26, the remaining structures and functions are the same as the embodiment described in FIG. 2, and details are not described herein again. FIG. 6 is a schematic architectural diagram of a high-speed transmission circuit and an input/output apparatus of the high-speed transmission circuit according to a sixth embodiment of the present invention. Referring to FIG. 6, in addition to octagonal pads of the first transmission pad 14 and the second transmission pad 16, as well as trapezoidal recessed portions of the first recessed portion 24 and the second recessed portion 26, the remaining structures and functions are the same as the embodiment described in FIG. 3, and details are not described herein again.

In an embodiment, referring to FIG. 1 and FIG. 4, the first grounding pad 20 and the second grounding pad 22 have enough area for routing. To be specific, a height h of the first grounding pad 20 can meet a requirement of setting at least one first grounding wire (not shown in the figure), and a height h of the second grounding pad 22 can meet a requirement of setting at least one second grounding wire (not shown in the figure), so that the first grounding pad 20 can be connected to an external grounding apparatus through at least one first grounding wire, and the second grounding pad 22 can be connected to the external grounding apparatus through at least one second grounding wire, to prevent problems such as mutual interference between the first transmission pad 14 and the second transmission pad 16 and poor signal quality.

In an embodiment, referring to FIG. 2, FIG. 3, FIG. 5, and FIG. 6, a height h1 of the first grounding unit 201 of the first grounding pad 20 and a height h2 of the first grounding unit 202 of the first grounding pad 20 need to meet a minimum height for setting a first grounding wire (not shown in the figure), so that at least one of the two first grounding units 201 and 202 of the first grounding pad 20 can be connected to an external grounding apparatus through at least one first grounding wire. In other words, the first grounding unit 201 bonds a first grounding wire, or the other first grounding unit 202 bonds a first grounding wire, or the two first grounding units 201 and 202 respectively bond a first grounding wire. Similarly, a height h1 of the second grounding unit 221 of the second grounding pad 22 and a height h2 of the second grounding unit 222 of the second grounding pad 22 need to meet a minimum height for setting a second grounding wire (not shown in the figure), so that at least one of the two second grounding units 221 and 222 of the second grounding pad 22 can be connected to the external grounding apparatus through at least one second grounding wire. In other words, the second grounding unit 221 bonds a second grounding wire, or the other second grounding unit 222 bonds a second grounding wire, or the two second grounding units 221 and 222 respectively bond a second grounding wire.

In one embodiment, the high-speed transmission circuits 30 are a peripheral component interconnect express apparatus (Peripheral Component Interconnect Express, PCIe), a universal serial bus apparatus (USB 3.0/3.1/3.2), a high-definition multimedia interface (High Definition Multimedia Interface, HDMI) apparatus, a display port (DisplayPort, DP) interface apparatus, and a serial advanced technology attachment (Serial Advanced Technology Attachment, SATA) apparatus.

Furthermore, all the embodiments mentioned above are based on two high-speed transmission circuits. On a single-chip system, if there are N high-speed transmission circuits on each side of the single chip, in comparison with the single chip system where the spacing between the transmission pad and the grounding pad is increased to twice (2*S) the original spacing(S) in the related art, a length of an outline edge of the single-chip system in the present invention can be reduced by 2*S*N, and an area can be reduced by (2*S*N)².

In conclusion, to shorten an outline of the high-speed transmission circuit and reduce parasitic capacitance between the transmission pad and the grounding pad, the present invention proposes the input/output apparatus that increases a horizontal distance between the transmission pad and the grounding pad through a design of the recessed portion on the grounding pad, to reduce the parasitic capacitance between the transmission pad and the grounding pad without adding an additional outline, thereby achieving good signal quality and also meeting a transmission signal specification.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. An input/output apparatus suitable for a plurality of high-speed transmission circuits, wherein the input/output apparatus comprises:
a plurality of transmission pad groups, wherein the plurality of transmission pad groups are of the same number as the high-speed transmission circuits and respectively correspond to the high-speed transmission circuits, each transmission pad group comprises a first transmission pad and a second transmission pad, and the first transmission pad and the second transmission pad are connected to the same side of a corresponding high-speed transmission circuit; and
a plurality of grounding pad groups, wherein the plurality of grounding pad groups are of the same number as the transmission pad groups and respectively correspond to the transmission pad groups, each grounding pad group comprises a first grounding pad and a second grounding pad, the first grounding pad and the second grounding pad are respectively located on two opposite outer sides of the first transmission pad and the second transmission pad and are at a spacing, a side that is of the first grounding pad and that is close to the first transmission pad is provided with a first recessed portion, and a side that is of the second grounding pad and that is close to the second transmission pad is provided with a second recessed portion, so that a first shortest distance between the first transmission pad and an inner edge of the first recessed portion and a second shortest distance between the second transmission pad and an inner edge of the second recessed portion are separately greater than the spacing.

2. The input/output apparatus according to claim 1, wherein the first shortest distance and the second shortest distance are at least twice the spacing.

3. The input/output apparatus according to claim 2, wherein the first grounding pad further comprises two first grounding units, and sides that are of the two first grounding units and that correspond to the first transmission pad form the first recessed portion together; and the second grounding pad further comprises two second grounding units, and sides that are of the two second grounding units and that correspond to the second transmission pad form the second recessed portion together.

4. The input/output apparatus according to claim 3, wherein there is a gap between the two first grounding units; and there is the gap between the two second grounding units.

5. The input/output apparatus according to claim 1, wherein the first transmission pad and the second transmission pad are polygonal pads, and the first recessed portion and the second recessed portion are matching recessed portions corresponding to the polygonal pads.

6. The input/output apparatus according to claim 1, wherein the first transmission pad and the second transmission pad are hexagonal pads, and the first recessed portion and the second recessed portion are triangular recessed portions corresponding to the hexagonal pads.

7. The input/output apparatus according to claim 1, wherein the first grounding pad is connected to an external grounding apparatus through at least one first grounding wire; and the second grounding pad is connected to the external grounding apparatus through at least one second grounding wire.

8. The input/output apparatus according to claim 7, wherein a height of the first grounding pad meets a minimum height for setting the at least one first grounding wire; and a height of the second grounding pad meets a minimum height for setting the at least one second grounding wire.

9. The input/output apparatus according to claim 3, wherein at least one of the two first grounding units is connected to an external grounding apparatus through at least one first grounding wire; and at least one of the two second grounding units is connected to the external grounding apparatus through at least one second grounding wire.

10. The input/output apparatus according to claim 9, wherein heights of the two first grounding units separately meet the minimum height for setting the first grounding wire; and heights of the two second grounding units separately meet the minimum height for setting the second grounding wire.

11. The input/output apparatus according to claim 1, wherein the high-speed transmission circuits are a peripheral component interactive connection apparatus (Peripheral Component Interconnect Express, PCIe), a universal serial bus apparatus (USB 3.0/3.1/3.2), a high-definition multimedia interface (High Definition Multimedia Interface, HDMI) apparatus, a display port (DisplayPort, DP) interface apparatus, and a serial advanced technology attachment (Serial Advanced Technology Attachment, SATA) apparatus.
